(19) United States
(12) Patent Application Publication
(10) Pub. No.: US 2015/0200340 A1
(43) Pub. Date: Jul. 16, 2015

(54) LIGHT-EMITTING DEVICE

(71) Applicant: KABUSHIKI KAISHA TOSHIBA, Tokyo (JP)

(72) Inventors: Haruhiko OKAZAKI, Ishikawa (JP); Takayoshi FUJII, Kanagawa (JP)

(21) Appl. No.: 14/474,054

(22) Filed: Aug. 29, 2014

(30) Foreign Application Priority Data
Jan. 14, 2014 (JP) 2014-004031

(51) Int. Cl. H01L 33/50; H01L 33/60; H01L 33/48; H01L 33/42

(52) U.S. Cl. CPC H01L 33/505; H01L 33/42; H01L 33/60; H01L 33/486

(57) ABSTRACT

According to one embodiment, a light-emitting device includes a light-emitting element. A first film covers the light-emitting element. A fluorescent film is provided on the first film and partially covers a region above a light extraction face of the light-emitting element. A transparent section is provided on the fluorescent film.

### CROSS-REFERENCE TO RELATED APPLICATION

This application is based upon and claims the benefit of priority from Japanese Patent Application No. 2014-004031, filed Jan. 14, 2014, the entire contents of which are incorporated herein by reference.

### FIELD

Embodiments described herein relate generally to light-emitting devices.

### BACKGROUND

Light-emitting diodes (LEDs) have been used in lighting, a backlight of a liquid crystal display device, or the like. To obtain white light used in lighting, a backlight, or the like, from a blue light emission LED, a fluorescent material that converts part of the emitted blue light into yellow light is sometimes applied to the blue light emission LED. In this case, as a result of mixing blue light from the LED and yellow light obtained by conversion by the fluorescent material, white light is output.

In general, the fluorescent material is adjusted based on the chromaticity balance or the intensity balance near the center of the LED where the emission intensity is high. However, at the end of an LED chip, the intensity of yellow light of the LED becomes relatively high and the intensity of blue light becomes relatively low. As a result, at the end of the LED chip, the chromaticity balance between blue light emission and yellow light emission is sometimes lost and the intensity of the yellow light becomes excessively high. When the chromaticity balance is lost in this manner, color unevenness in the light from the LED results.

### DESCRIPTION OF THE DRAWINGS

FIG. 1 is a sectional view illustrating an example of the structure of an LED according to a first embodiment,

FIG. 2 is a graph of a chromaticity change in an LED in which a fluorescent material is provided completely over a light-emitting face.

FIG. 3 is a graph of a chromaticity change in an LED in which a fluorescent material is provided completely over a light-emitting face and a lens contains a dispersant.

FIG. 4 is a graph of a chromaticity change in the LED according to the first embodiment.

FIG. 5 is a sectional view illustrating an example of the structure of an LED according to a second embodiment.

FIG. 6 is a sectional view illustrating an example of the structure of an LED according to a third embodiment.

FIG. 7 is a sectional view illustrating an example of the structure of an LED according to a fourth embodiment.

FIG. 8 is a sectional view illustrating an example of the structure of an LED according to a fifth embodiment.

### DETAILED DESCRIPTION

Embodiments provide a light-emitting device that is less likely to suffer color unevenness while maintaining emission intensity or brightness.

In general, according to one embodiment, a light-emitting device includes a light-emitting element. A first film covers the light-emitting element. A fluorescent film is provided on the first film and partially covers a region above a light extraction face of the light-emitting element. A transparent section is provided on the fluorescent film.

Hereinafter, embodiments will be described with reference to the drawings. The embodiments are not limited to those described below.

### First Embodiment

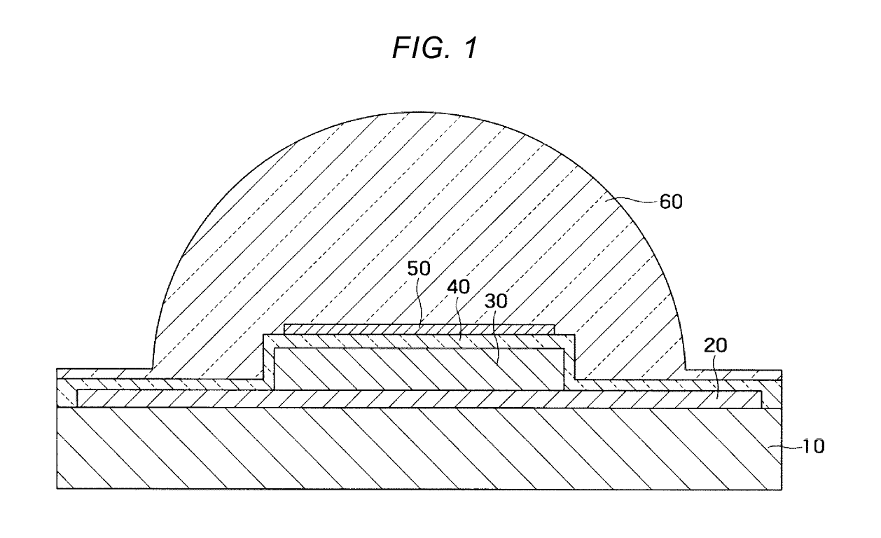

FIG. 1 is a sectional view illustrating an example of the structure of an LED 100 according to a first embodiment. The LED 100 includes a supporting substrate 10, an electrode 20, an LED chip 30, an intermediate film 40, a fluorescent film 50, and a lens 60.

The supporting substrate 10 is formed of, for example, an insulating material such as ceramic or a conductive material such as metal. The electrode 20 is formed on the supporting substrate 10 and is electrically connected to any portion of the LED chip 30. For example, the electrode 20 is electrically connected to the bottom of the LED chip 30 or a pad provided on the surface of the LED chip 30 via a wire.

The LED chip 30 as a light-emitting element is a semiconductor device that converts electric energy into light. The LED chip 30 has an active layer (not illustrated) provided between a P-type clad layer and an N-type clad layer on a chip substrate formed of sapphire, Si, or SiC. The LED chip 30 is a light-emitting element that emits blue light. When the LED chip 30 is made to emit light, a voltage is applied to the P-type clad layer and the N-type clad layer and holes and electrons are injected into the active layer. When the holes and the electrons injected into the active layer recombine with each other, the active layer emits light. If the substrate is formed of silicon, the light is emitted from a light-emitting face (a light extraction face) of the LED chip 30, and, if the substrate is formed of sapphire or SiC, the light is emitted from the entire chip substrate of the LED chip 30.

The intermediate film 40 as a first film covers the surface and the side faces of the LED chip 30. The intermediate film 40 covers the entire surface of the LED chip 30 and covers not only a central part of the surface thereof but also the end thereof. Moreover, the intermediate film 40 also covers the surface of the electrode 20. The refractive index of the intermediate film 40 is higher than the refractive index of the lens 60 and is lower than the refractive index of a surface portion of the LED chip 30. The intermediate film 40 is formed of, for example, a material such as a silicon dioxide film or a silicon nitride film.

The fluorescent film 50 is provided on the intermediate film 40 and covers a region above a central part of a top face (a light extraction face) of the LED chip 30. On the other hand, the fluorescent film 50 does not cover a region above the end of the LED chip 30. That is, the fluorescent film 50 has a size that is smaller than the area (the chip size) of the surface of the LED chip 30. For example, the width of the fluorescent film 50 is smaller than the width of the chip by about a few to several tens of micrometers. When the top face of the LED chip 30 is viewed from above, the outer edge of the fluorescent film 50 is located to the inside of the outer edge of the LED chip 30.

The fluorescent film 50 is formed of a material that may perform wavelength conversion on part of blue light from the LED chip 30 into yellow light, and is formed of, for example, a resin in which a fluorescent material such as YAG (yttrium aluminum garnet) doped with Ce (cerium) is dispersed. By mixing the blue light from the LED chip 30 and the yellow light obtained by conversion by the fluorescent film 50, it is possible to output white light.

The lens 60 is provided as a transparent section in such a way as to cover the fluorescent film 50 and the intermediate film 40 and has the shape of a convex lens (a hemispherical shape). The lens 60 is formed of a transparent resin. The material of the lens 60 may be the same material as the resin material of the fluorescent film 50, the resin material from which the fluorescent material is removed. The lens 60 does not contain a dispersant that disperses the light from the light-emitting element. Therefore, the lens 60 allows the light from the fluorescent film 50 or the intermediate film 40 to pass therethrough without attenuation. The refractive indexes of the lens 60 and the fluorescent film 50 are lower than the refractive index of the intermediate film 40. Thus, the lens 60 and the fluorescent film 50 may propagate the light from the LED chip 30 into the air with almost no reflection.

A method for producing the LED 100 according to this embodiment is as follows. The material of the electrode 20 is deposited on the supporting substrate 10. Next, by using lithography and etching, the material of the electrode 20 is processed. Then, a bonding paste is applied to the electrode 20, and the LED chip 30 is mounted thereon. Next, the material (for example, a resin or a dielectric) of the intermediate film 40 is deposited on the LED chip 30 by using sputtering, or the like. Incidentally, there is no need to provide the intermediate film 40 to the end of a package of the LED 100, and the intermediate film 40 simply has to be provided in a region in which light may be focused by the lens 60. Then, the material (for example, a resin into which a fluorescent material is mixed) of the fluorescent film 50 is partially applied to the intermediate film 40 located above the central part of the surface of the LED chip 30. Alternatively, the fluorescent film 50 may be formed by cutting a resin sheet containing a fluorescent material into an appropriate size and pasting the cut sheet to the central part of the surface of the LED chip 30. Next, the lens 60 (a resin whose refractive index is lower than the refractive index of the intermediate film 40) is formed on the intermediate film 40 and the fluorescent film 50. As a result, the LED 100 according to this embodiment is completed.

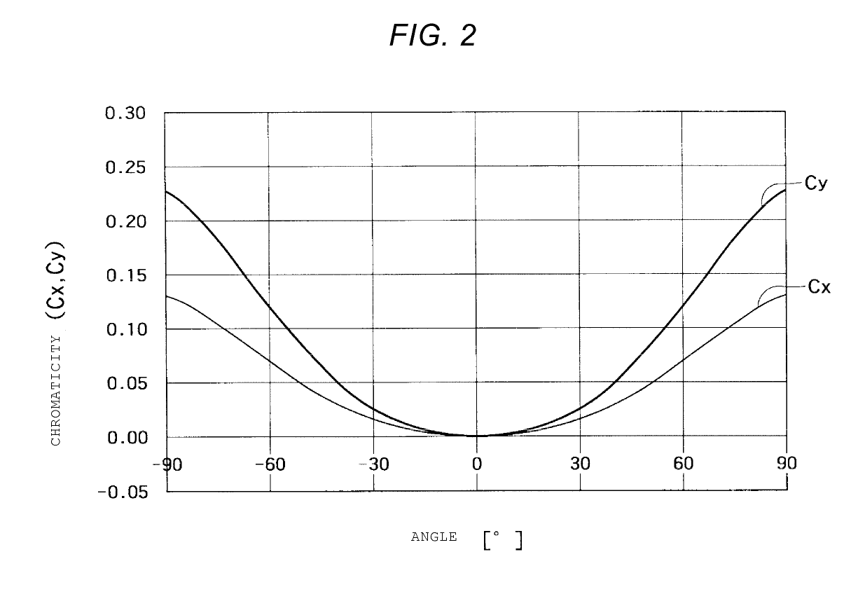

In general, when a fluorescent film is provided completely over the surface of an LED and a lens does not contain a dispersant, at the end of the LED, the intensity of yellow light of the LED becomes higher than the intensity of blue light. Therefore, even when the chromaticity balance between blue light emission and yellow light emission is adjusted in the central part of a light-emitting face of the LED to obtain white light, the chromaticity balance is lost at the end of the light-emitting face of the LED. For example, FIG. 2 is a graph of a chromaticity change in an LED in which a fluorescent material is provided completely over a light-emitting face. Incidentally, a lens of this LED does not contain a dispersant. In the graph of FIG. 2, a vertical direction (a frontal direction) with respect to a light-emitting face of the LED is an angle of 0 degree, and the angle formed with the frontal direction is indicated on the horizontal axis. The vertical axis represents the chromaticity (Cx, Cy) of a so-called xy chromaticity diagram. Cx indicates the chromaticity in the x direction, and Cy indicates the chromaticity in the y direction. Here, it is assumed that the chromaticity to obtain white light is set such that Cx=0.33 and Cy=0.33, and this value is used as a reference value. In the graph, an origin (0) of the vertical axis corresponds to a reference value (Cx=0.33, Cy=0.33).

As illustrated in FIG. 2, when viewed from the front (0 degree) of the light-emitting face of the LED, the chromaticity balance of blue light and yellow light is appropriate and white light is obtained. However, when viewed from the end of the light-emitting face of the LED, the chromaticity of the yellow light is high and the light looks like yellow. That is, even when the fluorescent material is provided, there is a large difference between Cx and Cy (or a large difference from the reference value) at the end of the LED and color unevenness is developed in the light from the LED. The reason why color unevenness is developed at the end of the LED in this way is as follows. When the light-emitting face of the LED is viewed from an oblique direction, since the light from the LED passes through the fluorescent material obliquely, the path in the fluorescent material through which the light passes becomes relatively long. Therefore, much of the light output in an oblique direction of the light-emitting face of the LED is converted into yellow. Thus, when the light-emitting face of the LED is viewed from an oblique direction, the light from the LED contains many yellow light components and is tinged with yellow. As a result, color unevenness is developed at the end of the LED.

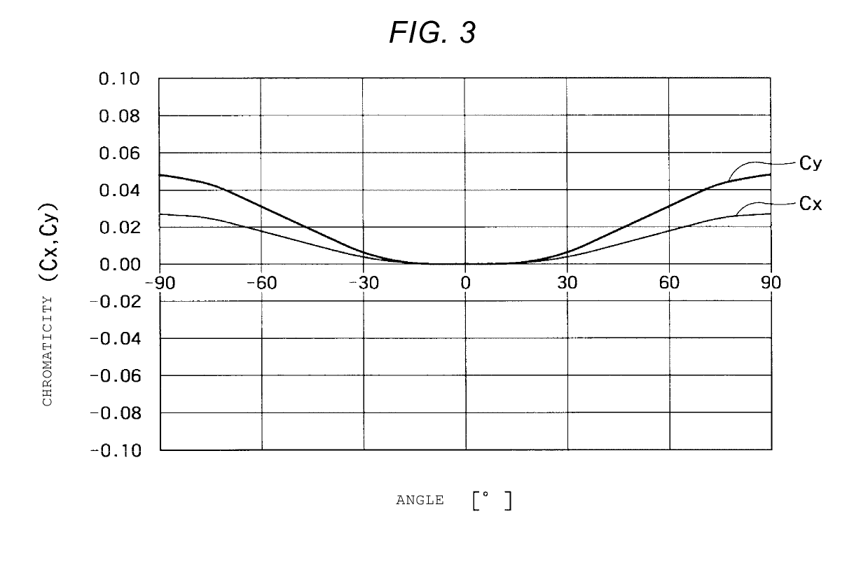

FIG. 3 is a graph of a chromaticity change in an LED in which a fluorescent material is provided completely over a light-emitting face and a lens contains a dispersant (for example, TiO₂ having 1 nm to 5 μm in particle diameter). Since the light from the front of the LED and the light from the end of the LED are mixed by the dispersant, chromaticity shift is relatively small at the end of the LED. That is, chromaticity unevenness is suppressed. However, the light intensity or the brightness of the entire LED is decreased by the dispersant. Incidentally, the dispersant obtains white light by dispersing or mixing the blue and the yellow light from the LED. Therefore, the dispersant may suppress color unevenness.

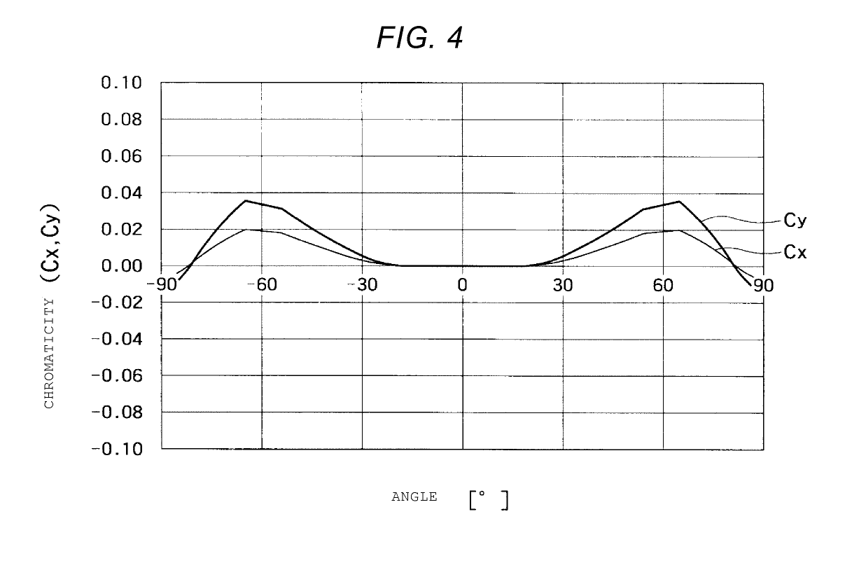

FIG. 4 is a graph of a chromaticity change in the LED 100 according to the first embodiment. In the LED 100 according to this embodiment, the fluorescent film 50 partially covers the central part of the light extraction face of the LED 100. As a result, part of blue light from the LED 100 is converted into yellow light by the fluorescent film 50. Therefore, when the LED 100 is viewed from the front of the light extraction face, there is almost no difference in chromaticity (Cx, Cy) and the chromaticity (Cx, Cy) becomes almost the reference value (Cx=0.33, Cy=0.33). That is, the light from the LED 100 looks like white light.

Moreover, the intermediate film 40 is interposed between the LED chip 30 and the fluorescent film 50. The intermediate film 40 has a higher refractive index than the fluorescent film 50 and the lens 60. Therefore, the critical angle from the intermediate film 40 to the fluorescent film 50 is relatively small, and the light from the LED chip 30 is easily reflected in the interface between the intermediate film 40 and the fluorescent film 50. Thus, part of blue light from the LED chip 30 enters the interface between the intermediate film 40 and the fluorescent film 50 at an angle which is greater than the critical angle and is reflected. The reflected blue light is subjected to multiple reflection and is guided to the end of the LED chip 30. Since the fluorescent film 50 does not cover the end of the LED chip 30, the guided blue light is extracted from the end of the LED chip 30 to the lens 60. The light passing through the fluorescent film 50 in an oblique direction contains many yellow light components, and the intermediate film 40 guides part of the blue light to the end of the LED chip 30. Therefore, the intermediate film 40 supplies many blue light components to both ends of the LED chip 30. As a result, as illustrated in FIG. 4, even at the end of the LED chip 30, the chromaticity (Cx, Cy) becomes closer to the reference value (Cx=0.33, Cy=0.33). That is, according to this embodiment, by partially providing the fluorescent film 50 in the central part of the LED chip 30 and providing the intermediate film 40 between the fluorescent film 50 and the LED chip 30, part of the blue light is propagated to the end of the LED chip 30. As a result, the LED 100 may output white light with small chromaticity shift not only from the central part of the LED chip 30 but also from the end thereof, and may output a uniform white light with less unevenness as a whole.

Thus, it is not necessary to add a dispersant to the lens 60, and it is possible to suppress a reduction in the light intensity or the brightness. That is, in this embodiment, the lens 60 is formed of a transparent material containing no dispersant. Therefore, the intensity or the brightness of the light from the LED chip 30 is not decreased greatly in the lens 60. Moreover, the light component (the yellow light component) converted into a long wavelength by the fluorescent film 50 is not reabsorbed by the active layer of the LED chip 30. This is because, due to a wide energy band gap of the active layer, a long wavelength light with low energy is not absorbed.

Incidentally, in the experiment, as compared to luminous flux of the LED described with reference to FIG. 3, luminous flux of the LED 100 according to this embodiment is increased by a factor of about 1.3. Therefore, the LED 100 according to this embodiment may output a uniform white light with less color unevenness while maintaining emission intensity or brightness.

The light-emitting section of the LED chip 30 is disposed near the central part of the lens 60. As a result, the light may suppress the total reflection component caused by the critical angle between the lens 60 and the air, which results in an improvement in the light extraction efficiency. At the same time, it becomes possible to control the light in such a way that intended light distribution characteristics are obtained.

### Second Embodiment

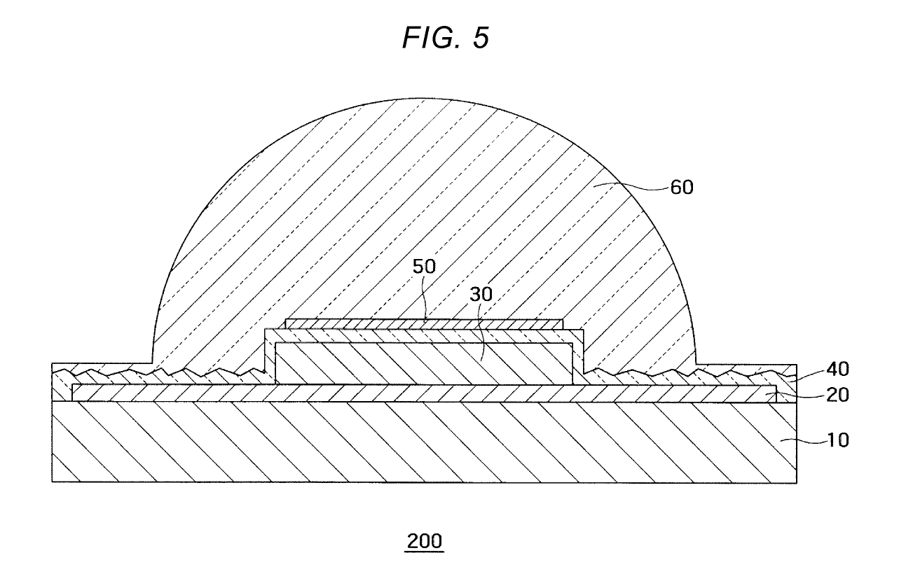

FIG. 5 is a sectional view illustrating an example of the structure of an LED 200 according to a second embodiment. The surface of an intermediate film 40 of the LED 200 has a shape that includes projections and depressions on both sides of an LED chip 30. The other structures of the LED 200 according to the second embodiment are similar to the corresponding structures of the LED 100 according to the first embodiment.

As a result of the surface of the intermediate film 40 having the shape that includes depressions and projections on both sides of the LED chip 30, the light is dispersed at the end of the LED 30, which makes it possible to extract the light from the end of the LED chip 30 more easily. Preferably, the size (a difference between the bottom of a depression and the peak of a projection) of the shape that includes depressions and projections of the intermediate film 40 is substantially equal to a light wavelength (for example, about 450 nm) which is extracted from the LED chip 30. This makes it easier to extract a light (for example, blue light) of an intended wavelength. This is because, since the light is dispersed without producing total reflection at the interface between the intermediate film 40 and the lens 60, the restriction of the critical angle at the interface is eliminated.

Furthermore, as is the case in the first embodiment, since the second embodiment has the intermediate film 40 and a fluorescent film 50 on the LED chip 30, the second embodiment may produce the same advantages as those of the first embodiment.

Incidentally, the surface of the intermediate film 40 on the surface of the LED chip 30 may also have the shape that includes depressions and projections. In this case, it becomes easier to extract a light from the surface of the LED chip 30.

### Third Embodiment

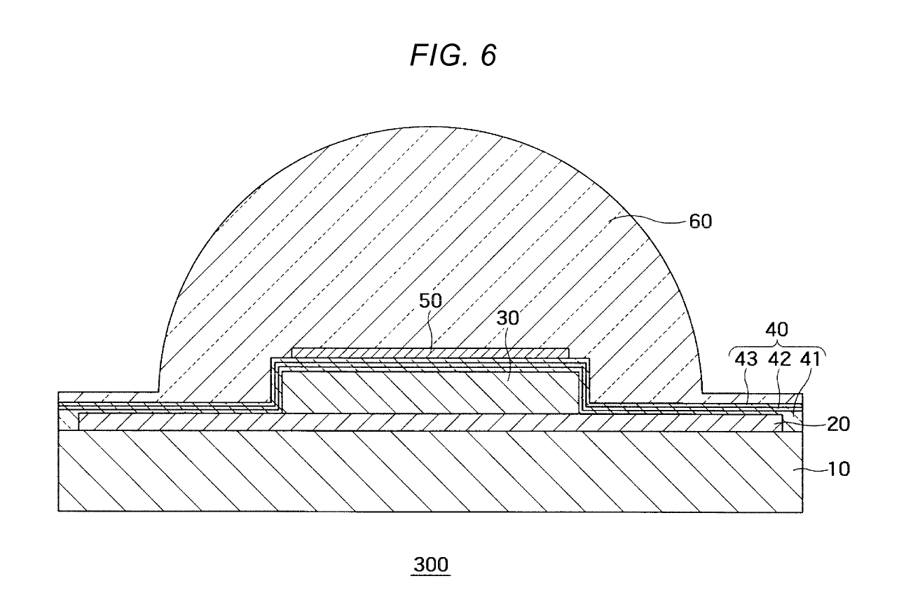

FIG. 6 is a sectional view illustrating an example of the structure of an LED 300 according to a third embodiment. An intermediate film 40 of the LED 300 is a multi-layer film in which a plurality of material layers 41 to 43 with different refractive indexes are stacked. The refractive index of the material layer 41 is lower than the refractive index of an LED chip 30. The refractive index of the material layer 42 is lower than the refractive index of the material layer 41. The refractive index of the material layer 43 is lower than the refractive index of the material layer 42 and is higher than the refractive index of a fluorescent film 50. The material layer 41 is formed of a material with a high refractive index, such as SiNx, ZrO, and TiO₂. The material layer 42 is formed of a material with an intermediate refractive index, such as HFO₂, ZnO, and Al₂O₃. The material layer 43 is formed of a material with a low refractive index, such as SiO₂. The other structures of the LED 300 according to the third embodiment may be similar to the corresponding structures of the LED 100 according to the first embodiment.

As described above, the refractive index of the intermediate film 40 according to the third embodiment is high in the light extraction face of the LED chip 30, and gradually gets lower as the intermediate film 40 gets closer to the fluorescent film 50. As a result, total reflection is less likely to occur in the material layers 41 to 43, which makes it possible to extract the light from the LED chip 30 efficiently.

Since it is possible to extract weak light emission from the end of the LED chip 30 efficiently, the LED 300 according to the third embodiment may output white light with smaller chromaticity shift at the end of the LED chip 30 and may output a uniform white light with less unevenness as a whole.

As is the case in the first embodiment, since the third embodiment has the intermediate film 40 and the fluorescent film 50 on the LED chip 30, the third embodiment may further produce the same advantages as those of the first embodiment. The third embodiment maybe combined with the second embodiment. As a result, the third embodiment may further produce the advantages of the second embodiment.

### Fourth Embodiment

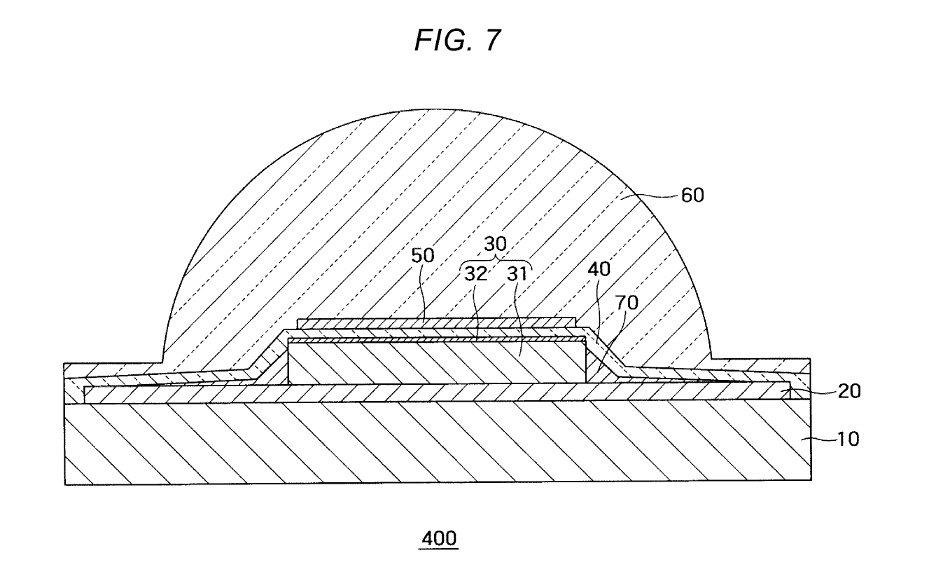

FIG. 7 is a sectional view illustrating an example of the structure of an LED 400 according to a fourth embodiment. The LED 400 further includes a reflective film 70 that covers the side faces of an LED chip 30 and is provided under an intermediate film 40. That is, in the fourth embodiment, on both sides of the LED chip 30, the reflective film 70 is provided. The reflective film 70 may be, for example, a resin containing white material that reflects light. The other structures of the LED 400 according to the fourth embodiment may be similar to the corresponding structures of the LED 100 according to the first embodiment.

Incidentally, the reflective film 70 may be formed as follows. For example, after the LED chip 30 is mounted on an electrode 20, the material (for example, a resin in the form of liquid) of the reflective film 70 is applied thereto and is then hardened. Since the liquid tends to accumulate on the side faces of the LED chip 30, the reflective film 70 is left in the form illustrated in FIG. 7. In this way, the reflective film 70 may be formed. The process of formation of the other structural components of the LED 400 may be similar to the corresponding formation process of the LED 100.

If a substrate 31 of the LED chip 30 is formed of a material (for example, silicon) that absorbs light, the reflective film 70 may suppress absorption of light from the side faces of the substrate 31. Moreover, the reflective film 70 may reflect the light guided into the intermediate film 40 efficiently in the direction in which a lens 60 is located. As a result, it is possible to suppress loss of light and improve light extraction efficiency. Furthermore, as is the case in the first embodiment, since the fourth embodiment has the intermediate film 40 and a fluorescent film 50 on the LED chip 30, the fourth embodiment may produce the same advantages as those of the first embodiment. Incidentally, alight-emitting section 32 includes a light-emitting layer provided on the substrate 31 and a reflective layer that is provided on the light-emitting layer and reflects light to the side where the lens 60 is located.

The fourth embodiment may be combined with any one of the second and third embodiments or both. As a result, the fourth embodiment may produce the advantages of any one of the second and third embodiments or both.

### Fifth Embodiment

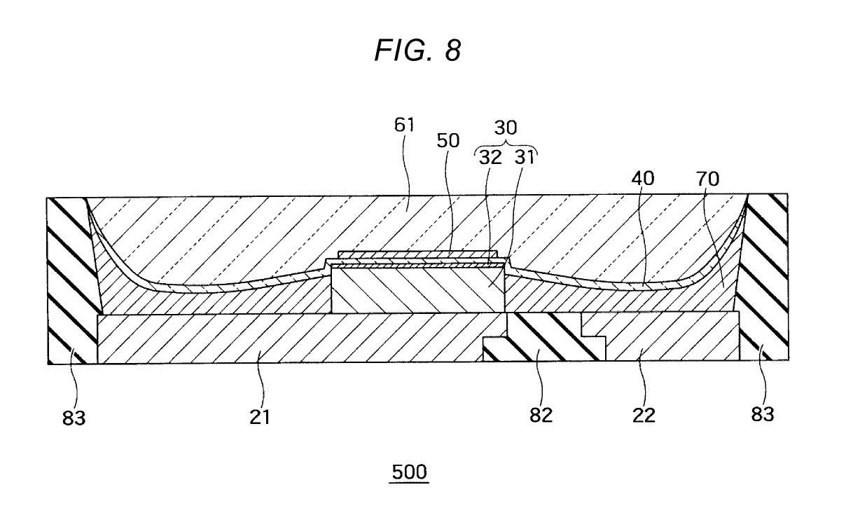

FIG. 8 is a sectional view illustrating an example of the structure of an LED 500 according to a fifth embodiment. In the fifth embodiment, the bottom and the top face of the LED 500 are formed to be a flat face. Therefore, a transparent section 61 does not have the shape of a lens and has a flat shape.

At both ends of the LED 500, a side-wall reflecting section 83 is provided. The side-wall reflecting section 83 surrounds the outer edge of the LED 500. The side-wall reflecting section 83, electrodes 21 and 22, and a bottom reflecting section 82 function as a container housing an LED chip 30, a reflective film 70, an intermediate film 40, a fluorescent film 50, and the transparent section 61. The side-wall reflecting section 83 and the bottom reflecting section 82 may be a resin containing white material that reflects light, for example. Therefore, the side-wall reflecting section 83 and the bottom reflecting section 82 have the function of reflecting the light from the LED chip 30.

The electrodes 21 and 22 are electrically connected to a pad of the LED chip 30 via a wire or are electrically connected to a substrate 31.

Next, a method for producing the LED 500 will be described. First, in the material of the electrodes 21 and 22, the bottom reflecting section 82 and the side-wall reflecting section 83 are formed. Next, the LED chip 30 is mounted on the electrode 21. As a result, a state in which the LED chip 30 is disposed in a container formed of the side-wall reflecting section 83, the electrodes 21 and 22, and the bottom reflecting section 82 is obtained. Next, as the material of the reflective film 70, a liquid resin is dropped into the container formed of the side-wall reflecting section 83, the electrodes 21 and 22, and the bottom reflecting section 82. At this time, an appropriate amount of the material of the reflective film 70 is dropped into a space between the LED chip 30 and the side-wall reflecting section 83. As a result, by using the surface tension, as illustrated in FIG. 8, between the LED chip 30 and the side-wall reflecting section 83, the reflective film 70 is formed. After the reflective film 70 is hardened, the intermediate film 40, the fluorescent film 50, and the transparent section 61 are formed in this order. After the formation of the transparent section 61, the transparent section 61 is made to have a substantially flat shape. As a result, the LED 500 illustrated in FIG. 8 is completed.

As is the case in the fourth embodiment, the LED 500 according to the fifth embodiment further includes the reflective film 70 that covers the side faces of the LED chip 30 and is provided under the intermediate film 40. As a result, as is the case in the fourth embodiment, when a substrate 31 of the LED chip 30 is formed of a material (for example, silicon) that absorbs light, the fifth embodiment may suppress absorption of light from the side faces of the substrate 31. Moreover, the reflective film 70, the side-wall reflecting section 83, and the bottom reflecting section 82 may reflect the light guided into the intermediate film 40 efficiently in the direction in which the transparent section 61 is located.

Furthermore, as is the case in the first embodiment, since the fifth embodiment has the intermediate film 40 and the fluorescent film 50 on the LED chip 30, the fifth embodiment may produce the same advantages as those of the first embodiment.

The fifth embodiment may be combined with any one of the second to fourth embodiments. As a result, the fifth embodiment may further produce the advantages of any one of the second to fourth embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A light-emitting device comprising:
a light-emitting element;
a first film that covers the light-emitting element;
a fluorescent film that is provided on the first film and partially covers a region above a light extraction face of the light-emitting element; and
a transparent section that is provided on the fluorescent film.

2. The light-emitting device according to claim 1, wherein
the fluorescent film covers a central part of the light extraction face of the light-emitting element and does not cover edge portions of the light extraction face of the light-emitting element.

3. The light-emitting device according to claim 1, wherein
a refractive index of the first film is higher than a refractive index of the transparent section.

4. The light-emitting device according to claim 1, wherein
a surface of the first film has a shape that includes projections and depressions.

5. The light-emitting device according to claim 4, wherein a distance from a bottom of the depressions and a peak of the projections is substantially equal to a wavelength of light emitted by the light-emitting element.

6. The light-emitting device according to claim 1, wherein
a refractive index of the first film is high on a side of the light-emitting element where the light extraction face is located, and gradually gets lower as the first film gets closer to the fluorescent film.

7. The light-emitting device according to claim 1, wherein the first film has multiple layers and the layers closer to the light extraction face has a higher refractive index relative to the layers closer to the fluorescent film.

8. The light-emitting device according to claim 1, further comprising:
a reflective film that covers side faces of the light-emitting element, and is provided under the first film.

9. The light-emitting device according to claim 1, wherein the light-emitting element includes a substrate and an active layer provided on the substrate.

10. The light-emitting device according to claim 9, wherein the substrate is one of a sapphire substrate, a silicon substrate or a silicon carbide substrate.

11. A light-emitting device comprising:
a light-emitting element;
a first film that covers the light-emitting element;
a fluorescent film that is provided on the first film and partially covers a region above a light extraction face of the light-emitting element; and
a transparent section that is provided on the fluorescent film and contains material that allows light emitted by the light-emitting element through the first film and through the fluorescent film without attenuation.

12. The light-emitting device according to claim 11, wherein the light-emitting element includes a substrate and an active layer provided on the substrate.

13. The light-emitting device according to claim 12, wherein
a refractive index of the first film is higher than a refractive index of the transparent section and is lower than a refractive index of a surface portion of the light-emitting element.

14. The light-emitting device according to claim 12, wherein the substrate is one of a sapphire substrate, a silicon substrate or a silicon carbide substrate.

15. The light-emitting device according to claim 11, wherein the transparent section is a lens.

16. The light-emitting device according to claim 11, wherein
the fluorescent film covers a central part of the light extraction face of the light-emitting element and does not cover edge portions of the light extraction face of the light-emitting element.

17. A light-emitting device comprising:
a light-emitting element;
a housing for the light-emitting element including a bottom part on which the light-emitting element is mounted and side parts that surround the light-emitting element, the bottom part including first and second electrodes and a first reflecting section between the first and second electrodes, the side parts including a second reflecting section;
a first film that covers the light-emitting element;
a fluorescent film that is provided on the first film and partially covers a region above a light extraction face of the light-emitting element; and
a transparent section that is provided on the fluorescent film.

18. The light-emitting device according to claim 17, further comprising:
a reflective film that covers side faces of the light-emitting element, and is provided between the first film and the bottom part of the housing.

19. The light-emitting device according to claim 18, wherein the reflective film extends from the side faces of the light-emitting element to the side parts of the housing to physically separate the first film and the bottom part of the housing.

20. The light-emitting device according to claim 17, wherein the transparent section has a flat upper surface.
